(19) United States
(12) Patent Application Publication
(10) Pub. No.: US 2001/0033478 A1
(43) Pub. Date: Oct. 25, 2001

(54) EMI and RFI shielding for printed circuit boards

(75) Inventors: Jesus Al Ortiz, San Jose, CA (US); Rocky R. Arnold, San Carlos, CA (US)

Correspondence Address: Craig P. Wong, TOWNSEND and TOWNSEND and CREW LLP, Two Embarcadero Center, 8th Floor, San Francisco, CA, 94111-3834, US

(73) Assignee: SHIELDING FOR ELECTRONICS, INC.

(21) Appl. No.: 09/788,263

(22) Filed: Feb. 16, 2001

Related U.S. Application Data
(60) Provisional application No. 60/198,769, filed on Apr. 21, 2000.
(60) Provisional application No. 60/203,263, filed on May 9, 2000.

(51) Int. Cl. H05K 9/00

(52) U.S. Cl. 361/818

(57) ABSTRACT

The present invention provides a vacuum deposited metal layer that can shield the electronic components on a PCB or FPC. The vacuum metallized conductive layer can be grounded to a ground trace on the circuit board to create a Faraday cage to protect the electronic components disposed on the circuit board from EMI. The metallized conductive layer can be disposed over an encapsulating insulative layer or onto a shaped thermoform or mold injected plastic substrate that is coupled to the PCB or FPC.

### CROSS-REFERENCES TO RELATED APPLICATIONS

The present application claims benefit from U.S. Provisional Patent Application Ser. Nos. 60/198,769, filed Apr. 21, 2000, entitled “EMI Shielding of Printed Circuit Boards and Flexible Circuit Boards and Flexible Circuits from Metallized Conformal Coatings” and Patent Application Ser. No. 60/203,263 filed May 9, 2000, entitled “Conformal Coating and Shielding of Printed Circuit Boards, Flexible Circuits, and Cabling,” the complete disclosures of which are incorporated herein by reference.

### BACKGROUND OF THE INVENTION

The present invention relates to methods and devices for shielding printed circuit boards and flexible circuitry from electromagnetic interference and radiofrequency interference.

Printed circuit boards (PCBs) and flexible circuitry (e.g., flexible printed circuity or FPCs) contain an array of passive and active components, chips (flip chip, bare die, and the like), grounding planes, traces, and connector leads. Current PCBs and FPCs contain high-speed processors and specialized chips having speeds of one gigahertz and higher for processing digital information and switching. Unfortunately, these microprocessors and chips can produce and be disrupted by electromagnetic interference (EMI), electrostatic discharge (ESD), and radiofrequency interference (RFI). (As subsequently used herein “EMI” shall include ESD, RFI, and any other type of electromagnetic emission or effect.)

Since electromagnetic radiation penetrating the device may cause electronic failure, manufacturers need to protect the operational integrity of their electronic products. In addition, emitted electromagnetic radiation can interfere with other components and emission levels are restricted by law. Controlling the electromagnetic interference can be accomplished through various means, including the use of metal housings (“cans”), metal-filled polymer housings, and metal liners for housings. Metal coatings on electronic housings are applied with conductive paints or metal plates, and adhere through chemical plating (electroless plating), or electroplating. Metal foils or liners with adhesive backings can be applied to the inside of the housing to enable electronic instruments to meet shielding requirements.

Unfortunately, each of the conventional solutions for EMI shielding for PCBs and FPCs have shortcomings. For example, plating is costly, complex and is limited to certain polymer resins. While silver paints have the good electrical properties, silver paint is extremely expensive. Nickel paints can be used for relatively low attenuation applications, but is limited by its high resistance and poor stability. Most importantly, the painting process has difficulties with flaking, cracking, and coating uniformity in recesses and creases.

Another example, U.S. Pat. No. 6,090,728 to Yenni, Jr. et al. recites an EMI article having a mat or grid of randomly oriented, low melting metal fibers between a nonporous carrier sheet and a thermoplastic fiber coat. The article is then heat staked onto the circuit board. Unfortunately, manufacturing of such an article has been found to be time consuming and unduly expensive. Moreover, the heat staking may unduly raise the temperature and damage the underlying microprocessor and chips disposed on the PCB.

Therefore, what are needed are simple and low cost methods and devices which can effectively shield PCBs and FPCs from electromagnetic interference.

### SUMMARY OF THE INVENTION

The present invention provides a vacuum deposited metal layer that can shield the electronic components on a PCB or FPC. The vacuum metallized conductive layer can be grounded to a ground trace on the circuit board to create a Faraday cage to protect the electronic components disposed on the circuit board from ESD. The metallized conductive layer can be disposed over an encapsulating insulative layer, onto a shaped thermoform sheet, or a mold injected plastic sheet that is coupled to the PCB or FPC. In any of the configurations, an insulating conformal coating can be applied over the conductive layer to insulate and/or waterproof the conductive layer.

The vacuum metallization method provides a low temperature process that creates a continuous and substantially uniform metallic layer that has high conductivity for shielding the underlying electronic components. For example, a vacuum metallized aluminum layer having a thickness of 3.0 microns to 12.0 microns provides shielding of 60 dB to 100 dB for the underlying electronic components.

In a first aspect, the present invention provides methods and systems of shielding an encapsulated electronic component. The electronic component can be disposed on the PCB or FPC and encapsulated with an insulating coating such as acrylic, urethane, one or two part epoxies, or the like. Thereafter, the metallized layer can be deposited over the insulating coating and grounded to a ground trace. The grounded metallized layer will help protect the underlying electronic components from EMI.

The conductive layer is typically vacuum metallized directly onto the insulating coating and the ground trace to shield the encapsulated electronic component. In some embodiments, an intermediate conductive layer can be deposited onto the insulating coating to improve adherence of the vacuum metallized layer.

Vacuum deposition creates a continuous and substantially uniform coating that provides superior shielding effectiveness across frequencies ranging from 30 MHz to frequencies above 3 GHz. It should be appreciated however, that the shielding effectiveness will be limited by the particulars of the material and design applications. Because the vacuum metallization process can add the metallization layer at a lower temperature, the underlying electronic component and insulating layer can be safely maintained at a temperature below approximately 200° C.

In some arrangements, individual or groups of electrical components can be insulated and metallized so as to reduce the cross talk between the components on the PCB.

In another aspect, the present invention provides a vacuum metallized thermoform EMI shield for the electronic components disposed on the PCB. Unlike injection molded plastics, which require a cleaning step to improve adhesion, thermoforms can be metallized without the assistance of cleaning compounds. Thus, the method of processing the EMI shield generally starts with a pre-treatment to modify the surface to improve adhesion. The thermoforms can be treated with a glow discharge or plasma etching. During this cycle the polymer substrate is impinged or bombarded by electrons and negative ions of inert or reactive gases. During the metal deposition cycle, a continuous, substantially uniform conductive layer is added over the surfaces and corners to provide a continuous shield.

The metallized mold injected plastic or thermoform can be attached to a ground trace of a PCB in a variety of manners. In exemplary configurations, a conductive adhesive can be coupled to the metallized mold injected plastic or thermoform to electrically couple the conductive layer to the ground trace. While it is possible to heat stake the metallized substrate onto the ground trace, such methods are not preferred due to the undesired effects of the raised temperature of the underlying electrical components. Unlike heat staking, coupling of the metallized substrate to the printed circuit board with a conductive adhesive does not expose the underlying electronic equipment to temperature increases during processing.

Applicants have found that vacuum metallizing a metal layer onto a thin thermoform can provide an effective shield having a uniform thickness that is less prone to cracking and flaking.

In some exemplary embodiments, the vacuum metallized thermoform can be coupled to the ground trace with a conductive adhesive. For example, preformed adhesive strips can be applied to the PCB ground trace or the thermoform to provide custom fitting EMI shields for printed circuit boards of computers, cellular phones, personal digital assistants (PDA's), or the like.

The thermoform can include a plurality of compartments that individually house the components or groups of components to reduce the amount of cross-talk between the electrical components attached to the printed circuit board.

In some arrangements, a top portion of the metallized thermoform can be detached from a base portion of the metallized thermoform. Such an arrangement allows a technician to access and/or replace the electronic components shielded by the metallized thermoform. The base portion of the metallized thermoform can remain attached to the ground trace while the top portion can be removed. An overlapping joint and connection assembly can be used to couple the top and base portions together and to maintain electrical continuity between the top and base portions.

Optionally, the thermoforms of the present invention can be coated on two sides to provide improved attenuation levels. Applicants have found that a double coating can attenuate EMI by at least 10 dB to 20 dB over conductive paint and single coated thermoforms. As an additional benefit, the double sided coating can reduce or eliminate the effect of a scratch (i.e. slot antenna) that would otherwise effect the overall shielding effectiveness of the shield.

In some exemplary embodiments of the present invention, a mold injected plastic substrate can be vacuum metallized to provide EMI shielding for the PCB components. In some manufacturing methods of the present invention, after placement of the electronic components onto the PCB, the PCB is moved through a heating process (typically convection reflow or IR reflow) that raises the overall temperature of the PCB, electronic components and EMI shield to a temperature ranging from 200° C. to 218° C. Applicants have found that mold injected plastic substrates being 30% glass filled, such as Supec resins, Ultem®, Noryl® HM resins, and Questra resins have a higher temperature capability (e.g. a melting point of approximately 220° C.) that can sufficiently withstand the heating process, while still providing a lightweight and effective EMI shield for the electronic components disposed on the PCB.

The concepts of the present invention are also applicable to flexible circuitry. As noted, the metallized thermoforms are more flexible than the conventional thicker, rigid plastic housings and the vacuum metallized conductive layer has been found to be less prone to flaking and cracking.

For a further understanding of the nature and advantages of the invention, reference should be made to the following description taken in conjunction with the accompanying drawings.

### BRIEF DESCRIPTION OF THE DRAWINGS

FIG. 1 shows a circuit board covered with a conformal coating;

FIG. 2 shows a circuit board covered with a conformal coating and a grounded metallization layer;

FIG. 3 shows a conformal coating, a grounded metallized layer, and nonconductive outer coating over a circuit board having a dam around an outer periphery of the printed circuit board;

FIG. 4 shows a circuit board of FIG. 3 without the dam;

FIG. 5 shows a metallized conformal coating having a nonconductive outer coating;

FIGS. 6A and 6B illustrate two embodiments of a metallized thermoformed sheet coupled to a ground trace of a circuit board;

FIGS. 7A and 7B show a compartmentalized EMI shield for a printed circuit board;

FIG. 7C is a close-up of a via through the compartmentalized thermoform that allows the metallized layer to contact the ground trace;

FIG. 8 shows an exploded view of a compartmentalized shield, a preshaped conductive adhesive and a printed circuit board having a ground trace and electronic components;

FIG. 9 illustrates a metallized thermoform having a top portion removably coupled to a base portion;

FIG. 10A illustrates a separated metallized thermoform having a tab and groove connection assembly;

FIG. 10B is a top view of the detachable lid having ventilation holes;

FIG. 10C is a side view of a locking hinge on the detachable lid;

FIG. 11 illustrates a metallized thermoform having overlapping top and base portions and a press fit connection assembly; and

FIG. 12 illustrates a top and bottom portion having a plurality of protrusions or bumps disposed around a periphery of the connection interface.

### DESCRIPTION OF THE SPECIFIC EMBODIMENTS

The present invention provides methods and systems for shielding electronic components on printed circuit boards and flexible circuits from electrostatic discharge, electromagnetic interference, and radiofrequency interference. In exemplary configurations, a conductive coating can be applied through vacuum metallization over an encapsulating insulative layer to shield the encapsulated electronic component. The conductive layer can be electrically coupled to a ground trace of the circuit board to ground the conductive shield. In another exemplary configuration, a metallized thermoform can be coupled to the ground trace to prevent the impingement and emission of the EMI energy.

The EMI shields of the present invention typically employ an electrically conductive layer which is able to prevent the emission and impingement of EMI radiation. In most configurations, the conductive layer will have a thickness between approximately 1.0 microns and 50.0 microns so as to be effective in blocking the passage of EMI. It should be appreciated, however that the thickness of the conductive layer is directly related to the type of target EMI radiation. For higher frequency emissions the conductive layer can be thin. On the other hand, for lower frequency emissions the thickness of the conductive layer should be increased.

A wide variety of metals and metal alloys can be used to create the EMI shield. For example, the conductive EMI shield can be comprised of vaporized aluminum, silver, copper, gold, tin, nickel-chromium alloy, or other conductive metals or alloys. For some materials, to increase bonding, it may be necessary to deposit two or more layers of conductive material over the electronic component. For example, a nickel-chromium alloy can be applied over the insulating layer prior to bonding aluminum over the insulating layer.

The conductive layer of the EMI shield will typically have a flash or melting temperature in the range of approximately 1200° C. to about 1250° C. The conductive layer will typically be applied for a time period less than approximately three seconds, such that thermal application of the conductive layer over the conformal layer does not unduly raise the temperature of the underlying electronic components, printed circuit board, or insulating layer. By the time the vaporized metal layer reaches the thermoform or injection molded substrate, the temperature of the metallized layer will typically be only approximately 105° F.

The conductive shield can be applied over the insulating layer in a variety of ways. The metal layer can be applied through painting, sputtering, electroplating, chemical plating, Zinc arc spraying, thermal evaporation, cathode sputtering, ion plating, electron beam, cathodic-arc, vacuum thermal spraying, vacuum metallization, electroless plating, vacuum plating, adhesion of a metal layer with an adhesive, or the like. The conductive layer -may be a vaporized metal, a substrate containing metal powder or fibers, or the like.

In preferred embodiments, the conductive layer will be applied through a vacuum metallization process so as to provide a substantially uniform shield over the electronic components. For example, in one exemplary embodiment, a substantially uniform conductive layer can be thermally evaporated directly onto the insulating encapsulant disposed over the electrical component.

Optionally, an insulating conformal layer can be applied over the conductive layer to insulate and/or waterproof the conductive layer from surrounding elements. The top insulating layer can be the same material as the underlying insulating layer or a different material.

In another exemplary embodiment, a thermoformed sheet can have a metallic coating thermally vaporized onto the sheet. By vacuum metallizing the already shaped thermoform, a substantially uniform conductive layer can be created over the surfaces and creases of the sheet. To ground the conductive layer, the conductive layer can have electrical contact with a ground trace or ground plane on the circuit board.

Prior to metallization, the thermoform can be pretreated to improve adhesion. One method of improving adhesion is through a glow discharge process in which the polymer substrate is bombarded with electrons and negative ions of inert or reactive gases to treat the surface. Inert gases such as argon and nitrogen, along with reactive gases such as oxygen, nitrous oxide, and various fluoride and chlorine compounds and gas mixtures can be used. The gas plasma is subsequently ignited with voltages from 2 kV to 5 kV and currents from 50 mA to 500 mA. Different chamber pressures, typically about 8×10⁻⁶ Torr, and cycle duration (30 seconds to 10 minutes) can affect the surface treatment.

During the metal deposition cycle, heat is generated and the distance from the deposition source to the thermoform is chosen. In a vacuum, there is no conduction or convection of heat but the radian energy from the evaporative source can warp, stress-relieve, and even melt the polymer forms, especially in the corners or deep draws where the film is drawn to its thinnest dimension. Thermal properties and wall thickness of the thermoform sheet, heat output of the evaporative source, distance from the source to substrate, duration of vaporization, and rotation of the substrate are all variables which need consideration. A more complete description of vacuum metallization can be found in U.S. Pat. No. 5,811,050 issued to Gabower, the complete disclosure of which is incorporated herein by reference While the remaining discussion focuses on the metallizing thermoforms, it should be appreciated that the present invention can also be utilized for the metallization of other substrates, such as injection molded plastics. While injection molded parts need mold release and ejector pin lubricants which can contaminate the injection molded parts, and often require cleaning to ensure adhesion of the EMI coating to the injection molded parts, the injection molded parts have a higher temperature capability than thermoforms which allows it to withstand higher temperature processing.

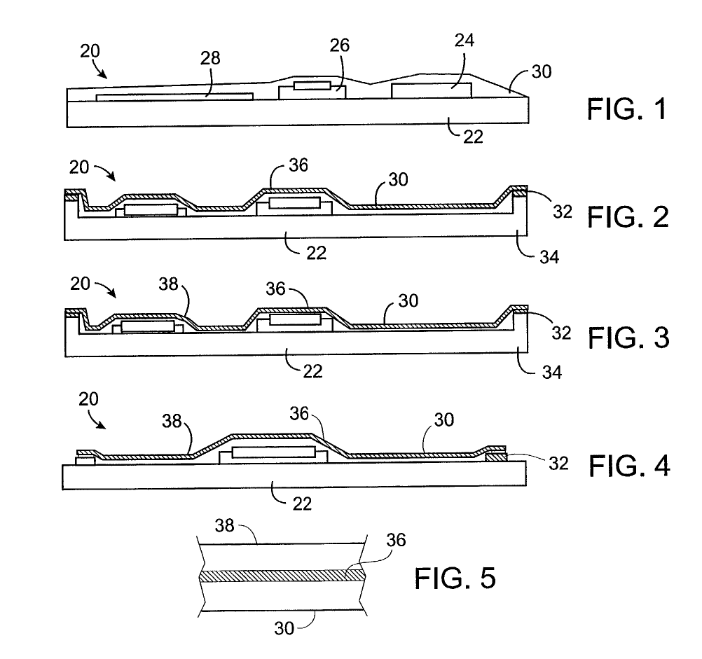

Referring now to FIG. 1, the present invention provides a printed circuit board 20 having an EMI radiation shield. The printed circuit board 20 can include a substrate 22 (such as FR-4, FR-5, Rogers Series materials, or the like) having various electrical components etched or attached thereto. For example, the circuit board 20 may have one or more active components 24 (e.g., semiconductor chips), passive components 26, (e.g., a resistor, capacitor, and the like), and traces 28 coupled to or formed on the substrate. These components can be covered or encapsulated with an insulating coating 30 to protect the elements from physical damage, fluid or gas damage, and the like. As shown in FIGS. 2 to 4, many printed circuit boards can include ground trace(s) 32 or a ground plane disposed on the substrate. In the embodiment shown in FIGS. 2 to 4, the ground trace 32 is disposed around a periphery of the printed circuit board 20. As will be describe further hereinbelow, the ground trace 32 can be positioned between the components, or on other portions of the printed circuit board 20.

In the exemplary embodiment shown in FIGS. 2 and 3, a peripheral dam 34 can be disposed under the ground trace 32 to hold the insulating coating 30 within the substrate during manufacturing. FIG. 4 illustrates a circuit board 20 without a dam.

The encapsulant insulative coating 30 can be composed of an acrylic, urethane, a one or two part epoxies, or other conventional or proprietary insulative materials. The insulating coating 30 will be applied such that the electrical components disposed on the substrate 22 are at least partially encapsulated. In preferred embodiments, the electrical components are completely encapsulated. During manufacturing, the insulating layer 30 can be deposited onto the substrate 22 and over the electrical components 24, 26 using conventional methods to encapsulate the electronic components. It should be appreciated that the electrical components can be individually encapsulated with areas of insulation or the electrical components can be encapsulated in groups, depending on the EMI shielding needs of the specific components. For example, in some printed circuit boards, it may be desirable to separately encapsulate and shield a microprocessor from the surrounding electronic components. In other configurations, it may be beneficial to encapsulate and shield the microprocessor with an adjacent electrical component.

The ground trace can be disposed on a dam 34 to raise the ground trace 32 above the encapsulant 30. In other methods, the encapsulant 30 can be etched or otherwise removed to expose the ground trace 32 to the conductive layer. A conductive layer 36 can then be vacuum metallized, or otherwise applied onto the insulating layer 30 and ground trace 32 to form the EMI radiation shield. As shown in FIGS. 2 and 3, the conductive layer will be electrically coupled to the ground trace 32 so as to ground the conductive layer 36.

Referring now to FIG. 5, the printed circuit boards 20 of the present invention can also include a conformal top layer 38 to insulate the EMI radiation shield 36 from surrounding electronics. The nonconductive top layer 38 can be the same or different material as the underlying insulating layer 30. In a specific embodiment, the conformal top layer can be waterproof so as to prevent infiltration of deleterious liquids in the atmosphere.

As will be understood by those of skill in the art, the present invention may be embodied in other specific forms without departing from the essential characteristics thereof. For example, the methods of the present invention are equally applicable to flexible printed circuitry substrates such as Kapton®, polyimide, or the like.

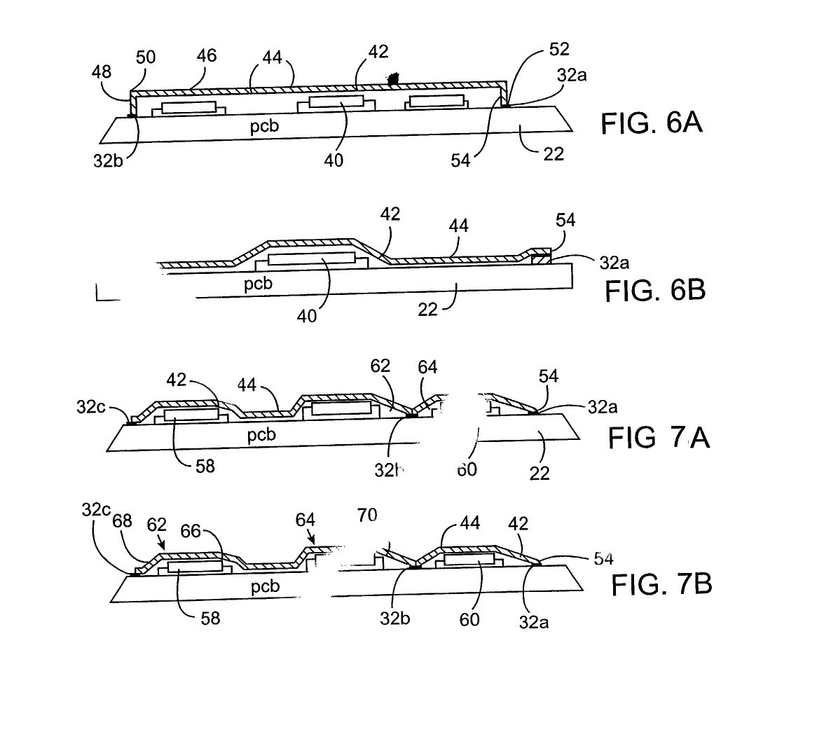

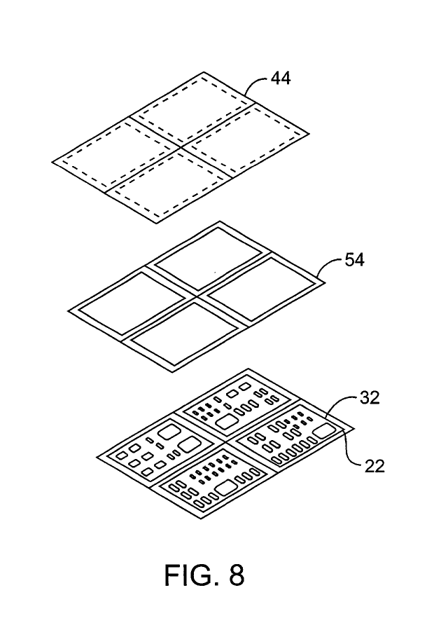

In another aspect, the present invention provides a metallized thermoform for shielding electronic components on a printed circuit board. As illustrated in FIGS. 6A and 6B, the metallized thermoform can be coupled to ground traces 32a, 32b on the substrate 22 that surround the electronic component 40. A metal layer 44 on the thermoform 42 will be coupled to ground traces 32a, 32b to ground the metallized thermoform. The metallized layer 44 can be coupled to the ground trace 32a, 32b in a variety of ways. For example, in one method, the metallized thermoform can be coupled to the ground trace with a conductive adhesive 54 (FIG. 8). The conductive adhesive 54 can be applied to attachment surfaces 52 of the thermoform or directly onto a predetermined pattern over the ground trace 32. In other embodiments, the conductive adhesive can be a custom pre-shaped adhesive strip that is shaped to conform to the shape of the ground trace on the printed circuit board and/or the shape of the contact surfaces of the metallized thermoform. In yet other methods, the conductive adhesive can be dispensed onto the thermoform or ground trace with conventional methods, such as screen printing, dispensing with a syringe, or the like.

In the embodiment in FIG. 6A the thermoform includes a top surface 46 and sidewalls 48. An edge or crease 50 is disposed at the juncture of the top surface 46 and the sidewalls. In preferred methods, the metallized layer is vacuum metallized onto the thermoform after shaping of the thermoform sheet so as to provide a substantially uniform thickness over the top surface 46, sidewalls 48 and edges 50. In an alternative embodiment illustrated generally in FIG. 6B, the thermoform 42 can be shaped in a curved or domed configuration so as to reduce the angles of the crease or even eliminate the crease entirely. While it is possible to metallize the thermoform prior to shaping, Applicants have found that during thermoforming of a metallized sheet, the stretching at the creases can stretch and thin the metallized layer so as to detrimentally effect the shielding capability of the metallized layer.

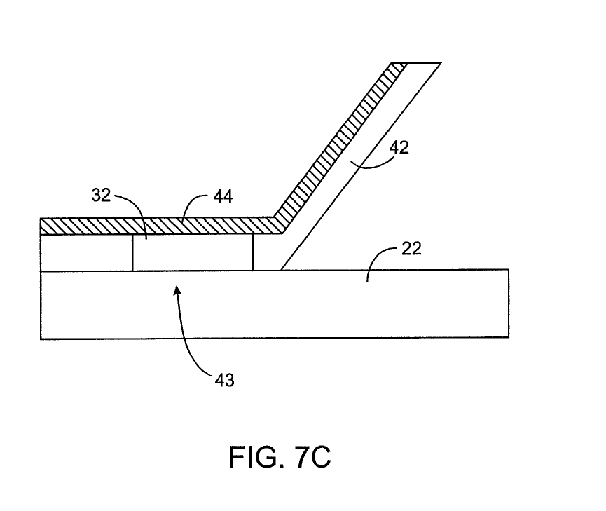

In another aspect, the present invention provides a compartmentalized EMI radiation shield that can reduce or prevent cross-talk between the various electronic components 58, 60 disposed on the circuit board. As shown in FIG. 7A, the EMI shield can include a thermoform 42 having a metallized layer 44 that shields a plurality of electronic components on the printed circuit board 22. A plurality of compartments 62, 64 can be shaped into the thermoform to separate the electrical components 58, 60. The metallized thermoform 42 can be grounded to the ground trace(s) 32a, 32b, 32c on the printed circuit board to create the EMI shield for the printed circuit board.

As shown in FIG. 7A, the thermoform 42 can be shaped to have a plurality of substantially curved or domed compartments that surround and shield the electrical components. The domed configuration is advantageous due to the decrease in the amount of creases and thin areas of the metallized layer. While FIG. 7A illustrates only a single electrical component disposed within each compartment, it should be appreciated that a plurality of electrical components can be disposed within each compartment, if desired.

In the embodiment illustrated in FIG. 7B, the metallized thermoform is shaped to have a top surface 66, outer walls 68 and at least one inner wall 70. In such embodiments, the compartments 62, 64 are defined by the top surface 66, inner walls 70, and outer walls 68. The inner wall 70 can be configured to contact the ground trace 32 between the adjacent components 62, 64 to ground the metallized thermoform around each of the electrical component 58, 60. The inner wall can be adhesively coupled or press fit onto the ground trace 32b.

In an exemplary embodiment illustrated in FIG. 7C, the thermoform (or mold injected plastic) 42 can include a via 43 that is alignable with the ground trace 32, such that when the thermoform is seated on the PCB 22, the ground trace extends through the via 43 in the thermoform to contact the metallized layer 44 disposed on the top surface of the thermoform substrate 42. While not shown, a conductive adhesive can be disposed in the via to couple the metallized layer 44 to the ground trace 32. Moreover, an insulating top layer can be placed over the metallized layer 44 to insulate the metallized layer from surrounding electronic components.

As illustrated in FIG. 8, the ground trace 32 can be disposed around a each of the separate electrical components (or groupings of electrical components). Such a configuration allows the shield to contact the ground trace around each of the components so as to shield the individual component from the adjacent components. The compartmentalized and metallized shield 44 can be coupled to the ground trace with a conductive adhesive 54, or the like. In other embodiments, the ground trace 32 may only be disposed around the periphery of the printed circuit board or only around a portion of each of the electrical components. Moreover, while not shown, the thermoform may be metallized on both the inner and outer surfaces to improve shielding.

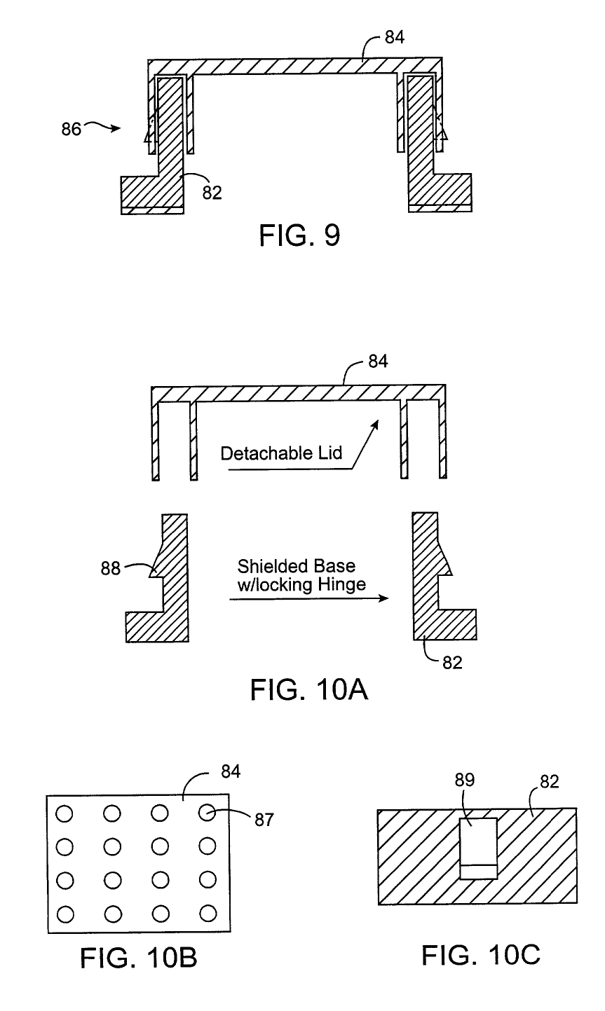

In another aspect, the present invention provides a EMI shield having a detachable top portion. Unlike conventional EMI shields, the base portion can remain attached to the ground trace so as to allow a technician to access the electronic components disposed within the EMI shield without disrupting the electrical continuity of the EMI shield with the ground trace. FIG. 9 shows a base portion 82 of the metallized substrate attached to the ground trace with a conductive adhesive (not shown). As shown in FIGS. 9 and 10A, a top portion 84 of the metallized thermoform can be removably attached to the base portion 82. As shown in FIG. 10B, the top portion 84 can have ventilation holes 87 to allow for heat dissipation. The holes are typically sized between 0.050 inches and 0.100 inches so as to allow ventilation, while still preventing EMI radiation leakage.

A connection assembly 86 can be coupled to the base portion 82 and top portion 84 to create a connection between the base and top portion. The metallized thermoform can be metallized on a plurality of surfaces so that there is sufficient electrical continuity between the base portion and top portion.

One exemplary connection assembly 86 is illustrated in FIGS. 10A and 10C. As shown, the base portion 82 includes a tab 88 and the top portion 84 has a corresponding groove 89 that can receive the tab 88. When connected, the top portion 84 will at least partially overlap the base portion 82 so as to prevent EMI leakage into and out of the shield.

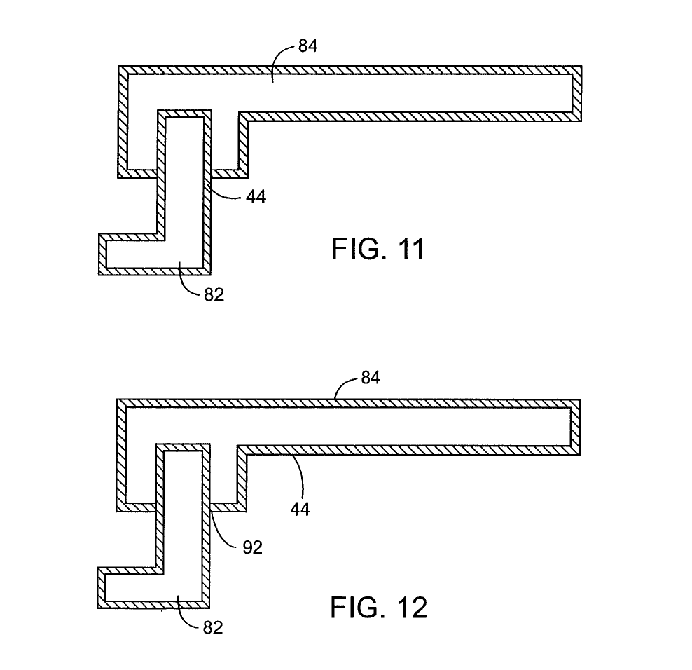

In an alternative embodiment illustrated in FIG. 11, the top portion 84 can simply be press fit in an overlapping configuration over the base portion 82. Optionally, as shown in FIG. 12 the top and/or base portion can include protrusions or bumps 92 to facilitate the press fit between the top and bottom portion. The protrusions 92 can be positioned around a periphery of the thermoform portions and sized and spaced to provide a minimized spacing between the interlocking portions. Preferably, the spacing 94 will be smaller than one-half the wavelength of the emissions from the electronic component shielded by the metallized thermoform. A more complete description of the protrusions and bumps is described in co-pending PCT Patent Application No. 00/27610, filed Oct. 6, 2000 (Attorney Docket No. 020843-000300PC).

While all the above is a complete description of the preferred embodiments of the inventions, various alternatives, modifications, and equivalents may be used. For example, one modification is to metallize the thermoform on both sides. Double metallizing has been found to provide 10 dB to 20 dB more shielding effectiveness. Moreover, the double shielding provides additional insurance against the formation of scratches (i.e. slot antennas). In such embodiments, an insulating conformal layer can be disposed over at least one of the metallization layers to insulate the metallized layers from surrounding conductive components. Additionally, it may be desirable to mask certain portions of the thermoform to prevent metallization and the like. Moreover, while most of the illustrated embodiments show the metallized layer along an outer surface of the substrate, it is possible to metallize the substrate along an inner surface. In such embodiments, the metallized layer can be insulated so as to prevent shorting out the electronic components. Accordingly, the foregoing description is intended to be illustrative, but not limiting, of the scope of the invention which is set forth in the following claims.

What is claimed is:

1. A circuit board comprising:
a substrate;
a ground trace and at least one electronic component coupled to the substrate;
a conformal insulating coating disposed on the substrate to encapsulate the electronic component; and
a conductive layer vacuum metallized over the insulating coating and contacting the ground trace, wherein the grounded conductive layer forms an electromagnetic interference shield for the electronic component.

2. The circuit board of claim 1 wherein the conductive layer is a thermally vaporized onto the conformal insulating coating.

3. The circuit board of claim 2 wherein the vacuum metallized layer comprises aluminum, copper, silver, gold, tin, nickel, or chromium.

4. The circuit board of claim 2 wherein the vacuum metallized layer has a thickness between approximately one micron and fifty microns.

5. The circuit board of claim 1 further comprising a conformal layer disposed over the conductive layer, wherein the conformal layer can protect the metallized layer and electrically isolate the metallized layer from adjacent components.

6. The circuit board of claim 5 wherein the conformal layer comprises acrylic, urethane, one-part epoxy, or two-part epoxy.

7. The circuit board of claim 5 wherein the conformal layer is waterproof.

8. The circuit board of claim 1 wherein the ground trace is positioned at least around a periphery of the substrate.

9. The circuit board of claim 1 wherein the at least one electronic component comprises a first and second component, wherein the ground trace runs between the first and second component.

10. The circuit board of claim 9 wherein the insulating layer comprises a first and second insulating layers and the conductive layer comprises a first and second conductive layer, wherein the first electronic component encapsulated by the first insulating layer and first conductive layer and the second component is encapsulated by the second insulating layer and second conductive layer, wherein both the first and second conductive layers contact the ground trace.

11. The circuit board of claim 1 further comprising a dam on the substrate, wherein the ground trace is positioned on the dam.

12. The circuit board of claim 1 wherein the substrate is flexible.

13. A method of EMI shielding a circuit board or flexible circuitry, the method comprising:
encapsulating an electronic component with a conforming insulating base coating;
applying a first conductive layer over the base coating; and
grounding the conductive layer to a ground trace to form an EMI shield for the electronic component.

14. The method of claim 13 wherein applying comprises vacuum metallizing the first conductive layer over the insulating coating.

15. The method of claim 14 further comprising maintaining a temperature of the component and base coating below approximately 200° C. during vacuum metallizing.

16. The method of claim 13 wherein the first conductive layer comprises aluminum, copper, silver, gold, tin, or nickel-chromium.

17. The method of claim 13 further comprising applying a second conductive layer over the first conductive layer

18. The method of claim 13 further comprising applying an insulating conformal layer over the first conductive layer.

19. The method of claim 18 wherein the conformal layer is waterproof.

20. The method of claim 13 wherein applying comprises adhering the conductive layer using a glow discharge process.

21. The method of claim 13 further comprising positioning the ground trace around a periphery of the component.

22. The method of claim 13 wherein the ground trace is disposed between a first and second component.

23. The method of claim 13 further comprising exposing the ground trace through the insulating coating.

24. A flexible circuitry comprising:
a flexible substrate;
a ground trace and a circuit coupled to the flexible substrate;
a conformal coating attached to the flexible substrate over the circuit; and
a conductive layer disposed over the conformal coating and contacting the ground trace, wherein the grounded conductive layer forms an electromagnetic interference shield for the flexible circuitry.

25. The flexible circuitry of claim 24 wherein the flexible substrate comprises polyimide, Kapton or polyimide.

26. A circuit board comprising:
a substrate;
a ground trace and at least one electronic component coupled to the substrate; and
a thermoform comprising a vacuum metallized conductive layer, wherein the thermoform can be disposed over the electronic component and coupled to the ground trace.

27. The circuit board of claim 26 wherein the vacuum metallized conductive layer is applied through thermal vaporization.

28. The circuit board of claim 26 wherein the vacuum metallized conductive layer has a thickness between approximately one micron and fifty microns.

29. The circuit board of claim 26 wherein the thermoform is coupled to the ground trace with a conductive adhesive.

30. The circuit board of claim 29 wherein the conductive adhesive is a conductive adhesive strip that substantially conforms to a shape of the ground trace.

31. The circuit board of claim 30 wherein the thermoform further comprises a plurality of compartments, wherein the components are separated within the compartments to prevent cross-talk between the components.

32. The circuit board of claim 31 wherein the thermoform comprises a peripheral lip and wherein the plurality of compartments define a plurality of walls, wherein the plurality of walls and peripheral lip contact the ground trace.

33. The circuit board of claim 26 wherein the vacuum metallized layer comprises a thickness between 1.0 microns to 50.0 microns.

34. The circuit board of claim 26 wherein the vacuum metallized layer comprises aluminum, copper, tin, nickel, chromium, silver, or gold.

35. A method of shielding electronic components, the method comprising:
vacuum metallizing a conductive layer onto a thermoformed article;
attaching the vacuum metallized thermoform to a ground trace on a circuit board to form a grounded shield.

36. The method of claim 35 further comprising:
thermoforming a plurality of compartments into the thermoform; and
separating the electronic components into separate compartments of the thermoform so as to prevent cross-talking between the electronic components.

37. The method of claim 36 wherein attaching comprises coupling a conductive adhesive between the thermoform and the ground trace.

38. The method of claim 37 wherein coupling comprises dispensing the conductive adhesive onto one of the thermoform and the ground trace.

39. The method of claim 37 wherein coupling comprises screen printing the conductive adhesive on an attachment portion of the thermoform.

40. The method of claim 37 wherein the conductive adhesive is a preformed adhesive strip.

41. A shielded circuit board comprising:
a substrate comprising a ground trace;
at least a first and second electronic component disposed on the substrate; and
a substrate body comprising a vacuum metallized conductive layer, wherein the thermoform body comprises attachment surfaces that can be coupled to the ground trace;
wherein the substrate body comprises a first and second compartment such that when the attachment surfaces are coupled to the ground trace, the first electronic component is disposed in the first compartment and the second electronic component is disposed in the second compartment.

42. The shielded circuit board of claim 41 further comprising a conductive adhesive disposed between the attachment surfaces and the ground trace.

43. The shielded circuit of claim 41 wherein the first and second compartments are defined by a plurality of outer walls and an inner wall, wherein the inner wall contacts the ground trace between the first and second components.

44. The shielded circuit of claim 41 wherein the substrate body is a thermoform.

45. The shielded circuit of claim 41 wherein the substrate body comprises injection molded plastic.

46. A method of shielding electronic components on a circuit board, the method comprising:
providing a vacuum metallized substrate comprising a plurality of compartments;
coupling attachment surfaces of the metallized substrate to a ground trace on a circuit board with a conductive adhesive; and
separating electronic components into the compartments of the metallized substrate so as to prevent cross talk between the electronic components.

47. The method of claim 46 wherein the substrate comprises one of a thermoform and injection molded plastic.

48. The method of claim 46 wherein coupling comprises contacting an attachment surface against the ground trace between the electronic components.

49. The methods of claim 46 wherein the attachment surfaces completely surround the electronic components.

50. An EMI radiation shield for a circuit board, the shield comprising:
a metallized substrate body comprising a base portion, and a top portion removably attached to the base portion;
wherein the base portion comprises an attachment surface that can be bonded to a ground trace on the circuit board.

51. The EMI shield of claim 50 further comprising a conductive adhesive that can bond the attachment surfaces to the ground trace.

52. The EMI shield of claim 50 wherein the base portion and top portion are coupled to each other through an connection assembly.

53. The EMI shield of claim 52 wherein the connection assembly comprises a tab and groove, wherein one of the tab and groove is on the base portion and the other of the tab and groove is on the top portion.

54. The EMI shield of claim 52 wherein a periphery of the top portion overlaps a periphery of the bottom portion.

55. The EMI shield of claim 54 wherein at least one of the periphery of top portion and bottom portion comprises protrusions.

56. The EMI shield of claim 55 wherein the protrusions are spaced no farther than one-half a wavelength of the EMI radiation.

57. The EMI shield of claim 52 wherein the substrate body comprises a thermoform.

58. The EMI shield of claim 52 wherein the substrate body comprises injection molded plastic.

59. A method of shielding an electronic component, the method comprising:
attaching a base portion of a metallized substrate to the ground trace surrounding the electronic component; and
removably coupling a top portion of a metallized substrate to the base portion to cover the electronic component.

60. The method of claim 59 further comprising positioning a conductive adhesive over at least a portion of a ground trace.

61. The method of claim 59 wherein coupling comprises overlapping a portion of the top portion over the bottom portion.

62. The method of claim 59 wherein the top portion overlaps the bottom portion over a periphery of the bottom portion.

63. The method of claim 59 further comprising position protrusions between a periphery of the top portion and bottom portion of the EMI shield.

64. The method of claim 63 wherein the protrusions are spaced no larger than one-half a wavelength of electromagnetic radiation emitted from the electronic component.

65. The method of claim 59 wherein coupling comprises inserting a tab in a groove, wherein one of the tab and groove is disposed on the top portion and the other of the tab and groove is disposed on the bottom portion.

66. The method of claim 59 further comprising thermally evaporating a conductive layer onto the thermoform.

67. The method of claim 59 wherein the substrate body comprises one of a thermoform and injection molded plastic.

68. An EMI shield for components of a PCB, the shield comprising:
a substrate;
a ground trace and at least one electronic component coupled to the substrate; and
a mold injected plastic substrate comprising a vacuum metallized conductive layer, wherein the mold injected plastic substrate can be disposed over the electronic component and coupled to the ground trace.

69. The circuit board of claim 68 wherein the mold injected plastic is coupled to the ground trace with a conductive adhesive.

70. The circuit board of claim 69 wherein the conductive adhesive is a conductive adhesive strip that substantially conforms to a shape of the ground trace.

71. The circuit board of claim 70 wherein the mold injected plastic further comprises a plurality of compartments, wherein the components are separated within the compartments to prevent cross-talk between the components.

72. The circuit board of claim 71 wherein the mold injected plastic comprises a peripheral lip and wherein the plurality of compartments define a plurality of walls, wherein the plurality of walls and peripheral lip contact the ground trace.
